(19) United States
(12) Patent Application Publication
(10) Pub. No.: US 2025/0275296 A1
(43) Pub. Date: Aug. 28, 2025

(54) METHOD FOR DIE BONDING AN LED CHIP

(71) Applicant: FOSHAN NATIONSTAR OPTOELECTRONICS CO., LTD., Guangdong (CN)

(72) Inventors: Junzheng Li, Guangdong (CN); Mingjun Zhu, Guangdong (CN); Yurong Li, Guangdong (CN); Yan Chen, Guangdong (CN); Jundong Qiu, Guangdong (CN); Danwei Li, Guangdong (CN)

(73) Assignee: FOSHAN NATIONSTAR OPTOELECTRONICS CO., LTD., Guangdong (CN)

(21) Appl. No.: 19/012,491

(22) Filed: Jan. 7, 2025

(30) Foreign Application Priority Data
Jan. 8, 2024 (CN) 202410028608.9

(51) Int. Cl. H10H 20/01; H01L 23/00

(52) U.S. Cl. CPC H10H 20/0364; H01L 24/27; H01L 24/83; H01L 2224/27318; H01L 2224/8323

(57) ABSTRACT

A method for die bonding an LED chip includes S1: forming a preset adhesive droplet array corresponding to one pad on a substrate based on the area S of one LED chip and the radius R of an adhesive droplet formed by a dispensing device in a single dispensing action, where parameters of the preset adhesive droplet array include the number X of adhesive droplets in a horizontal direction, the number Y of adhesive droplets in a vertical direction, and a horizontal distance H between two horizontally adjacent adhesive droplets, and a vertical distance D between two vertically adjacent adhesive droplets; S2: dispensing a conductive adhesive onto the pad multiple times according to the preset adhesive droplet array to form a bonding portion; and S3: placing the LED chip on the bonding portion and curing the conductive adhesive.

### CROSS-REFERENCE TO RELATED APPLICATIONS

This application claims the priority of a Chinese Patent Application No. 202410028608.9, filed on Jan. 8, 2024, the disclosure of which is incorporated herein by reference in its entirety.

### TECHNICAL FIELD

The present application relates to the field of light-emitting diode (LED) technology, particularly a method for die bonding an LED chip.

### BACKGROUND

As a semiconductor device, an LED is a solid-state lighting device that can convert electrical energy into light energy. An LED has advantages such as small size, low power consumption, and long lifespan. LEDs are widely used in fields such as lighting, display, and communication.

An LED chip is the core component of an LED device. For a certain LED chip, the larger the chip size, the higher the brightness of the LED device. However, when an existing LED device uses a large-sized LED chip (≥20 mil), problems such as chip damage, failure, and poor conductivity are prone to occur.

### SUMMARY

In view of this, embodiments of the present application provide a method for die bonding an LED chip.

The present application is implemented through the following technical solution: A method for die bonding an LED chip is provided. The method includes providing a substrate. At least one pad is disposed in an array on the substrate. One pad is configured to place one LED chip. The method includes S1: forming a preset adhesive droplet array corresponding to the one pad based on the area S of the LED chip to be placed and the radius R of an adhesive droplet formed by a dispensing device in a single dispensing action, where parameters of the preset adhesive droplet array include the number X of adhesive droplets in the horizontal direction, the number Y of adhesive droplets in the vertical direction, and the horizontal distance

$$H = [ \begin{matrix}{H}_{11} & {H}_{12} & … & {H}_{1 ( X - 1 )} \\ {H}_{21} & {H}_{22} & … & {H}_{2 ( X - 1 )} \\ … & … & … & … \\ {H}_{Y 1} & {H}_{Y 2} & … & {H}_{Y ( X - 1 )}\end{matrix} ]$$

between two horizontally adjacent adhesive droplets, and the vertical distance

$$D = [ \begin{matrix}{D}_{11} & {D}_{12} & … & {D}_{1 ( X - 1 )} \\ {D}_{21} & {D}_{22} & … & {D}_{2 ( X - 1 )} \\ … & … & … & … \\ {D}_{Y 1} & {D}_{Y 2} & … & {D}_{Y ( X - 1 )}\end{matrix} ]$$

between two vertically adjacent adhesive droplets: S2:dispensing a conductive adhesive onto the pad multiple times according to the preset adhesive droplet array to form a bonding portion: and S3: placing the LED chip on the bonding portion and curing the conductive adhesive.

In one or more embodiments, the horizontal distance H between the adhesive droplets satisfies R<H<2R, and the vertical distance H between the adhesive droplets satisfies R<D<2R.

In one or more embodiments, in the preset adhesive droplet array,

$$60 \% * S < ( 2 R + {H}_{11} + {H}_{12} + … + {H}_{1 ( X - 1 )} ) * ( 2 R + {D}_{11} + {D}_{12} + … + {D}_{1 ( Y - 1 )} ) < S .$$

In one or more embodiments, in the preset adhesive droplet array, the horizontal distance between two horizontally adjacent adhesive droplets in the first row and the last row is greater than the horizontal distance between two horizontally adjacent adhesive droplets in rows between the first row and the last row, and the vertical distance between two vertically adjacent adhesive droplets in the first column and the last column is greater than the vertical distance between two vertically adjacent adhesive droplets in columns between the first column and the last column.

In one or more embodiments, the step S2 includes: first dispensing adhesive droplets at intervals in the horizontal direction and the vertical direction to form first paste positions, then dispensing adhesive droplets at positions adjacent to the first paste positions to form second paste positions, and finally dispensing adhesive droplets at remaining positions.

In one or more embodiments, the step S2 includes: first dispensing adhesive droplets at intervals in the horizontal direction and the vertical direction to form first paste positions and then dispensing adhesive droplets at remaining positions.

In one or more embodiments, the preset adhesive droplet array is a 3×3 array composed of 9 adhesive droplets.

In one or more embodiments, the horizontal distance between the center adhesive droplet and an adhesive droplet horizontally adjacent to the center adhesive droplet is smaller than the horizontal distance between adhesive droplets other than the center adhesive droplet, and the vertical distance between the center adhesive droplet and an adhesive droplet vertically adjacent to the center adhesive droplet is smaller than the vertical distance between adhesive droplets other than the center adhesive droplet.

In one or more embodiments, the preset adhesive droplet array is a 4×4 array composed of 16 adhesive droplets.

In one or more embodiments, a size of the LED chip is larger than or equal to 20 mil.

### BRIEF DESCRIPTION OF DRAWINGS

FIG. 1 is a substrate after die bonding in the related art.

FIG. 2 is a diagram of an adhesive droplet array according to one or more embodiments of the present application.

FIG. 3 is a diagram of an adhesive droplet array according to one or more embodiments of the present application.

FIG. 4 is a diagram of an adhesive droplet array according to one or more embodiments of the present application.

### DETAILED DESCRIPTION

In order that the preceding object, features, and advantages of the present application can be more apparent and easier to understand, examples of the present application are described below in detail in conjunction with drawings. Numerous specific details are set forth below to facilitate a thorough understanding of the present application. However, the present disclosure can be implemented in many modes different from the embodiments described herein, and those skilled in the art can make similar modifications without departing from the connotation of the present application, so the present application is not limited by the embodiments described below.

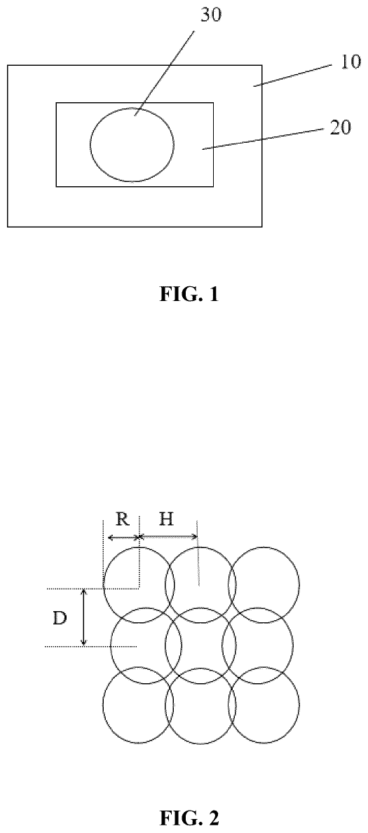

Technicians have analyzed the problems of chip damage, failure, and poor conductivity in existing chips and found that a significant influencing factor is the LED die bonding process. The LED die bonding process is a crucial step in the manufacturing of LED devices. In the LED die bonding process, an LED chip is secured to a substrate to achieve better electrical connection and heat dissipation. The existing LED die bonding process is typically completed using a die bonding machine. Referring to FIG. 1, the process includes dispensing a conductive adhesive 30 onto the pad 20 of the substrate 10, placing the LED chip onto the conductive adhesive 30, and curing the conductive adhesive 30. As shown in the FIG. 1, the conductive adhesive 30 is generally dispensed in a single action to cover the area of the pad 20 for carrying the LED chip.

Through the analysis of problem samples, it has been found that in the die bonding process, when an existing large-sized LED chip (≥20 mil) is bonded using the preceding dispensing method, the conductive adhesive between the LED chip and the substrate tends to have many voids. Under high-temperature conditions, the coefficient of thermal expansion of the air in the voids differs from that of the conductive adhesive, causing the LED chip to be easily damaged under stress. Additionally, when the junction temperature rises rapidly, the air in the voids is unable to effectively transfer the junction temperature of the LED chip via the conductive adhesive to the external of the device so as to dissipate heat, resulting in excessively high local temperature on the LED chip. If the temperature exceeds the maximum limit, the PN junction of the LED chip is damaged, leading to a failure. Moreover, the voids reduce the contact area between the bottom of the LED chip and the substrate pad, thereby decreasing the conductive path and reducing conductivity.

To address the problems of chip damage, failure, and poor conductivity caused by die bonding of a large-sized LED chip, the present application proposes a method for die bonding an LED chip. The method determines the number of adhesive dispensing actions based on the size of the LED chip and dispenses a conductive adhesive onto a pad multiple times. This method reduces the voids between the bottom of the LED chip and the substrate and lowers the risks of chip loss, failure, and poor conductivity of the LED device.

The following further describes embodiments of the present application with reference to drawings.

The method for die bonding an LED chip according to the present application includes the following steps S1, S2 and S3.

In step S1, a substrate is provided, where multiple pads are arranged in an array on the substrate.

The substrate may be a ceramic substrate, metal substrate, Bismaleimide Triazine (BT) substrate, glass substrate, or PCB board. The positions and sizes of the pads are set according to the requirements of the LED device by using common methods in the art, such as chemical plating, electroplating, or etching. This is not limited by the present application.

In step S2, the dispensing needle and the die bonding machine parameters are adjusted to determine the radius of each adhesive droplet and the distance between the adhesive droplets formed in a single dispensing action.

For a certain dispensing needle, the size of the adhesive droplet dispensed by the die bonding machine is influenced by the machine parameters. When determining the size of the adhesive droplet, the upper and lower limits of the radius of each adhesive droplet dispensed by the needle are determined, and then the machine parameters are adjusted to select a consistent and stable droplet radius R. Based on this droplet radius R, the distance between adhesive droplets is determined. The distance between adhesive droplets refers to the distance between the centers of adjacent adhesive droplets. The distance between adhesive droplets includes the horizontal distance H between two horizontally adjacent adhesive droplets and the vertical distance D between two vertically adjacent adhesive droplets. In the present application, R<H<2R, and R<D<2R.

In step S3, the number X of adhesive droplets in the horizontal direction and the number Y of adhesive droplets in the vertical direction are determined based on the area S of the LED chip and the distance between the adhesive droplets, forming a preset adhesive droplet array corresponding to one pad.

Compared with the related art where a conductive adhesive is applied in a single action, the method for die bonding an LED chip according to the present application determines the number of adhesive dispensing actions based on the size of the LED chip and dispenses a conductive adhesive onto the pad multiple times, thereby reducing the voids between the bottom of the LED chip and the substrate and lowering the risks of chip loss, failure, and poor conductivity of the LED device.

In the present application, the shape of the preset adhesive droplet array is approximately the same as that of the LED chip, ensuring an even distribution of the conductive adhesive at the bottom of the LED chip and consistent extrusion around the perimeter of the LED chip. For example, when the LED chip is square, the preset adhesive droplet array is a 3×3 array composed of 9 adhesive droplets or a 4×4 array composed of 16 adhesive droplets; and when the LED chip is rectangular, the preset adhesive droplet array is a 2×3 array composed of 6 adhesive droplets or a 2×4 array composed of 8 adhesive droplets.

For the adhesive droplets dispensed on the substrate, it is necessary to ensure that the conductive adhesive under the LED chip can spread evenly across the bonding pad after the LED chip is pressed down and to control the amount of adhesive extruded around the LED chip. Therefore, in the present application, the product of the horizontal width of the adhesive droplet array and the vertical width of the adhesive droplet array is greater than 60% of the area of the LED chip and less than the area of the LED chip. Additionally, in the preset adhesive droplet array, the horizontal distance between two horizontally adjacent adhesive droplets in the first row and the last row is greater than the horizontal distance between two horizontally adjacent adhesive droplets in rows between the first row and the last row, and the vertical distance between two vertically adjacent adhesive droplets in the first column and the last column is greater than the vertical distance between two vertically adjacent adhesive droplets in columns between the first column and the last column. Thus, the preset adhesive droplet array forms a pattern having protruding comers, with the central adhesive droplets relatively clustered and centered, ensuring that after the LED chip is placed, the central area of the bottom of the LED chip is less likely to have voids and that other adhesive droplets supplement the conductive adhesive, thus allowing the conductive adhesive to be evenly distributed on the bottom of the LED chip.

Referring to FIG. 2, the horizontal distance between two horizontally adjacent adhesive droplets is

$$H = [ \begin{matrix}{H}_{11} & {H}_{12} & … & {H}_{1 ( X - 1 )} \\ {H}_{21} & {H}_{22} & … & {H}_{2 ( X - 1 )} \\ … & … & … & … \\ {H}_{Y 1} & {H}_{Y 2} & … & {H}_{Y ( X - 1 )}\end{matrix} ] ,$$

and the vertical distance between two vertically adjacent adhesive droplets is

$$D = [ \begin{matrix}{D}_{11} & {D}_{12} & … & {D}_{1 ( X - 1 )} \\ {D}_{21} & {D}_{22} & … & {D}_{2 ( X - 1 )} \\ … & … & … & … \\ {D}_{Y 1} & {D}_{Y 2} & … & {D}_{Y ( X - 1 )}\end{matrix} ] .$$

Therefore, in terms of the pattern formed by the adhesive droplets, the horizontal width of the pattern is 2R+H₁₁+H₁₂+ . . . +H_{1(X-1}), and the vertical width of the pattern is 2R+D₁₁+D₁₂+ . . . +D_{1(Y-1)}. Thus, based on 60%*S<(2R+H₁₁+H₁₂+ . . . +H_{1 (X-1)})*(2R+D₁₁+D₁₂+ . . . +D_{1(Y-1)})<S, the number X of adhesive droplets in the horizontal direction and the number Y of adhesive droplets in the vertical direction are determined.

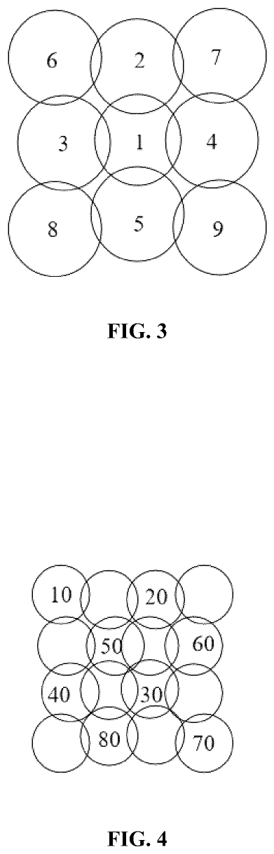

Referring to FIG. 3, in one or more embodiments of the present application, the radius of each adhesive droplet is R=0.375 mm, and the adhesive droplet array is a 3×3 array composed of 9 adhesive droplets. The central adhesive droplet 1 is horizontally or vertically 0.635 mm from each of the adhesive droplets 2, 3, 4, and 5 adjacent to the central adhesive droplet 1. The vertical distance between other adhesive droplets and the horizontal distance between other adhesive droplets are both 0.685 mm.

In step S4, in the region where the LED chip is to be placed, the adhesive droplets are first dispensed at intervals in the horizontal direction and the vertical direction to form the first paste positions, then the adhesive droplets are dispensed at positions adjacent to the first paste positions to form the second paste positions, and finally the adhesive droplets are dispensed at the remaining positions, where adhesive droplets at all paste positions are connected to each other to form the bonding portion.

If the adhesive droplets are dispensed in the order in which the adhesive droplets are arranged, adhesive droplets at adjacent paste positions may prematurely adhere to each other, causing an uneven distribution of the conductive adhesive on the pad and resulting in voids between the LED chip and the substrate. Therefore, the present application dispenses the adhesive droplets at intervals in the horizontal direction and the vertical direction to ensure that adhesive droplets at the first paste positions do not prematurely adhere to each other, then dispenses the adhesive droplets at the second paste positions adjacent to the first paste positions, and finally dispenses the adhesive droplets at the remaining positions. This ensures an even distribution of the conductive adhesive in the adhesive droplet array and prevents voids from forming between the LED chip and the substrate.

Specifically, the paste positions of the adhesive droplets are determined based on the radius, number, and distance of the adhesive droplets. This allows for the editing of the coordinate points of the paste positions in the control program of the die bonding machine, thereby controlling the order of dispensing the adhesive droplets. The following describes this with reference to embodiments.

FIG. 3 shows a 3×3 adhesive droplet array. Typically, the dispensing process starts from a vertex, as indicated by the adhesive droplet 6 in FIG. 3. Then, the adhesive droplet is dispensed after horizontally skipping one adhesive droplet, as indicated by the adhesive droplet 7 in FIG. 3. Next, the adhesive droplet is dispensed after vertically skipping one adhesive droplet, as indicated by the adhesive droplet 9 in FIG. 3. Finally, the adhesive droplet is dispensed after horizontally skipping one adhesive droplet, as indicated by the adhesive droplet 8 in FIG. 3. Thus, dispensing at the first paste positions is completed. The first paste positions 6, 7, 8, and 9 are not connected to each other both horizontally or vertically. Based on the first paste positions, the adhesive droplets are then dispensed at the second paste positions adjacent to the first paste positions, as indicated by the adhesive droplets 2→5→3→4 in FIG. 3. Finally, the adhesive droplets are dispensed at the remaining paste positions, as indicated by the adhesive droplet 1 in FIG. 3. The adhesive droplets 6, 7, 8, and 9 indicate the first paste positions, but the order of dispensing the adhesive droplets to 6, 7, 8, and 9 is not fixed. The order of dispensing the adhesive droplets to 6, 7, 8, and 9 may be clockwise, counterclockwise, or any other order. The same applies to the second paste positions and the remaining paste positions.

FIG. 4 shows a 4×4 adhesive droplet array. Typically, the dispensing process starts from a vertex, as indicated by the adhesive droplet 10 in FIG. 4. Then, the adhesive droplet is dispensed after horizontally skipping one adhesive droplet, as indicated by the adhesive droplet 20 in FIG. 4. Next, the adhesive droplet is dispensed after vertically skipping one adhesive droplet, as indicated by the adhesive droplet 30 in FIG. 4. Then, the adhesive droplet is dispensed after horizontally skipping one adhesive droplet, as indicated by the adhesive droplet 40 in FIG. 4. Subsequently, the adhesive droplet is dispensed in the middle of the already placed adhesive droplets, as indicated by the adhesive droplet 50 in FIG. 4. Following this, the adhesive droplet is dispensed after horizontally skipping one adhesive droplet, as indicated by the adhesive droplet 60 in FIG. 4. Then, the adhesive droplet is dispensed after vertically skipping one adhesive droplet, as indicated by the adhesive droplet 70 in FIG. 4. Finally, the adhesive droplet is dispensed after horizontally skipping one adhesive droplet, as indicated by the adhesive droplet 80 in FIG. 4. Thus, dispensing at the first paste positions is completed. The remaining paste positions are all adjacent to the first paste positions and are all called second paste positions.

In step S6, the LED chip is placed onto the bonding portion, and the conductive adhesive is cured.

In the present application, commonly used methods such as thermal curing or photo-curing may be used to cure the conductive adhesive, thereby achieving the connection between the LED chip and the substrate.

Compared with the related art where a conductive adhesive is applied in a single action, the method for die bonding an LED chip according to the present application determines the number of adhesive dispensing actions based on the size of the LED chip and dispenses a conductive adhesive onto the pad multiple times, thereby reducing the voids between the bottom of the LED chip and the substrate and lowering the risks of chip loss, failure, and poor conductivity of the LED device.

The technical features of the preceding embodiments may be combined in any manner. For brevity of description, all possible combinations of the technical features in the preceding embodiments are not described. However, as long as the combinations of these technical features do not conflict, such combinations are to be construed as being within the scope of the specification.

The preceding embodiments are merely several implementation modes of the present application. These embodiments are described in a specific and detailed manner but cannot be understood as a limit to the scope of the present application. It is to be noted that for those having ordinary skill in the art, several modifications and improvements may further be made without departing from the concept of the present application, and these modifications and improvements are within the scope of the present application. Therefore, the scope of the present application is defined by the appended claims.

What is claimed is:

1. A method for die bonding an LED chip, the method comprising providing a substrate, at least one pad being disposed on the substrate, one pad of the at least one pad being configured to place one LED chip, and the method comprising:
S1: forming a preset adhesive droplet array corresponding to the one pad based on an area S of the one LED chip to be placed and a radius R of an adhesive droplet formed by a dispensing device in a single dispensing action, wherein parameters of the preset adhesive droplet array comprise a number X of adhesive droplets in a horizontal direction, a number Y of adhesive droplets in a vertical direction, and a horizontal distance
$$H = [ \begin{matrix}{H}_{11} & {H}_{12} & … & {H}_{1 ( X - 1 )} \\ {H}_{21} & {H}_{22} & … & {H}_{2 ( X - 1 )} \\ … & … & … & … \\ {H}_{Y 1} & {H}_{Y 2} & … & {H}_{Y ( X - 1 )}\end{matrix} ]$$
between two horizontally adjacent adhesive droplets, and a vertical distance
$$D = [ \begin{matrix}{D}_{11} & {D}_{12} & … & {D}_{1 ( X - 1 )} \\ {D}_{21} & {D}_{22} & … & {D}_{2 ( X - 1 )} \\ … & … & … & … \\ {D}_{Y 1} & {D}_{Y 2} & … & {D}_{Y ( X - 1 )}\end{matrix} ]$$
between two vertically adjacent adhesive droplets;
S2: dispensing a conductive adhesive onto the pad multiple times according to the preset adhesive droplet array to form a bonding portion; and
S3: placing the LED chip on the bonding portion and curing the conductive adhesive.

2. The method for die bonding an LED chip according to claim 1, wherein the horizontal distance H between the adhesive droplets satisfies R<H<2R, and the vertical distance H between the adhesive droplets satisfies R<D<2R.

3. The method for die bonding an LED chip according to claim 2, wherein in the preset adhesive droplet array,
$$60 \% * S < ( 2 R + {H}_{11} + {H}_{12} + … + {H}_{1 ( X - 1 )} ) * ( 2 R + {D}_{11} + {D}_{12} + … + {D}_{1 ( Y - 1 )} ) < S .$$

4. The method for die bonding an LED chip according to claim 3, wherein in the preset adhesive droplet array, a horizontal distance between two horizontally adjacent adhesive droplets in a first row and a last row is greater than a horizontal distance between two horizontally adjacent adhesive droplets in rows between the first row and the last row, and a vertical distance between two vertically adjacent adhesive droplets in a first column and a last column is greater than a vertical distance between two vertically adjacent adhesive droplets in columns between the first column and the last column.

5. The method for die bonding an LED chip according to claim 1, wherein the step S2 comprises: first dispensing adhesive droplets at intervals in the horizontal direction and the vertical direction to form first paste positions, then dispensing adhesive droplets at positions adjacent to the first paste positions to form second paste positions, and finally dispensing adhesive droplets at remaining positions.

6. The method for die bonding an LED chip according to claim 2, wherein the step S2 comprises: first dispensing adhesive droplets at intervals in the horizontal direction and the vertical direction to form first paste positions, then dispensing adhesive droplets at positions adjacent to the first paste positions to form second paste positions, and finally dispensing adhesive droplets at remaining positions.

7. The method for die bonding an LED chip according to claim 3, wherein the step S2 comprises: first dispensing adhesive droplets at intervals in the horizontal direction and the vertical direction to form first paste positions, then dispensing adhesive droplets at positions adjacent to the first paste positions to form second paste positions, and finally dispensing adhesive droplets at remaining positions.

8. The method for die bonding an LED chip according to claim 4, wherein the step S2 comprises: first dispensing adhesive droplets at intervals in the horizontal direction and the vertical direction to form first paste positions, then dispensing adhesive droplets at positions adjacent to the first paste positions to form second paste positions, and finally dispensing adhesive droplets at remaining positions.

9. The method for die bonding an LED chip according to claim 1, wherein the step S2 comprises: first dispensing adhesive droplets at intervals in the horizontal direction and the vertical direction to form first paste positions and then dispensing adhesive droplets at remaining positions.

10. The method for die bonding an LED chip according to claim 2, wherein the step S2 comprises: first dispensing adhesive droplets at intervals in the horizontal direction and the vertical direction to form first paste positions and then dispensing adhesive droplets at remaining positions.

11. The method for die bonding an LED chip according to claim 3, wherein the step S2 comprises: first dispensing adhesive droplets at intervals in the horizontal direction and the vertical direction to form first paste positions and then dispensing adhesive droplets at remaining positions.

12. The method for die bonding an LED chip according to claim 4, wherein the step S2 comprises: first dispensing adhesive droplets at intervals in the horizontal direction and the vertical direction to form first paste positions and then dispensing adhesive droplets at remaining positions.

13. The method for die bonding an LED chip according to claim 5, wherein the preset adhesive droplet array is a 3×3 array composed of 9 adhesive droplets.

14. The method for die bonding an LED chip according to claim 6, wherein the preset adhesive droplet array is a 3×3 array composed of 9 adhesive droplets.

15. The method for die bonding an LED chip according to claim 7, wherein the preset adhesive droplet array is a 3×3 array composed of 9 adhesive droplets.

16. The method for die bonding an LED chip according to claim 8, wherein the preset adhesive droplet array is a 3×3 array composed of 9 adhesive droplets.

17. The method for die bonding an LED chip according to claim 13, wherein a horizontal distance between a center adhesive droplet and an adhesive droplet horizontally adjacent to the center adhesive droplet is smaller than a horizontal distance between adhesive droplets other than the center adhesive droplet, and a vertical distance between the center adhesive droplet and an adhesive droplet vertically adjacent to the center adhesive droplet is smaller than a vertical distance between adhesive droplets other than the center adhesive droplet.

18. The method for die bonding an LED chip according to claim 9, wherein the preset adhesive droplet array is a 4×4 array composed of 16 adhesive droplets.

19. The method for die bonding an LED chip according to claim 10, wherein the preset adhesive droplet array is a 4×4 array composed of 16 adhesive droplets.

20. The method for die bonding an LED chip according to claim 1, wherein a size of the LED chip is larger than or equal to 20 mil.
